(19) United States
(12) Patent Application Publication
(10) Pub. No.: US 2024/0186156 A1
(43) Pub. Date: Jun. 6, 2024

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Kenji ONO, Toyama (JP); Yusaku OKAJIMA, Toyama (JP); Takatomo YAMAGUCHI, Toyama (JP); Hideto TATENO, Toyama (JP); Yuji TAKEBAYASHI, Toyama (JP)

(21) Appl. No.: 18/436,677

(22) Filed: Feb. 8, 2024

Related U.S. Application Data
(63) Continuation of application No. PCT/JP2021/034902, filed on Sep. 22, 2021.

(51) Int. Cl. H01L 21/67; C23C 16/34; C23C 16/455; C23C 16/458; C23C 16/52; H01L 21/02

(52) U.S. Cl. CPC H01L 21/67109; C23C 16/345; C23C 16/45557; C23C 16/4583; C23C 16/52; H01L 21/0217

(57) ABSTRACT

A substrate processing apparatus, together with related techniques, is provided that includes: a reaction tube provided with a protrusion, wherein a substrate is processed in the reaction tube; a first heater configured to heat the reaction tube; a second heater configured to heat the protrusion; and a heat insulator provided at the protrusion.

### CROSS REFERENCE TO RELATED APPLICATIONS

This application is a bypass continuation application of PCT International Application No. PCT/JP2021/034902, filed on Sep. 22, 2021, in the WIPO, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

In a heat treatment process of a substrate in a manufacturing process of a semiconductor device, for example, a vertical type substrate processing apparatus may be used. In the vertical type substrate processing apparatus, a plurality of substrates are arranged into a substrate retainer of the vertical type substrate processing apparatus and supported in a vertical direction by the substrate retainer, and the substrate retainer is loaded into a process chamber of the vertical type substrate processing apparatus. Thereafter, a process gas is introduced into the process chamber while the process chamber is heated to perform a substrate processing such as a film-forming process on the plurality of substrates. For example, according to some related arts, the film-forming process is disclosed.

### SUMMARY

According to the present disclosure, there is provided a technique capable of improving a uniformity of heating a substrate.

According to an aspect of the present disclosure, there is provided a technique that includes: a reaction tube provided with a protrusion, wherein a substrate is processed in the reaction tube; a first heater configured to heat the reaction tube; a second heater configured to heat the protrusion; and a heat insulator provided at the protrusion.

### BRIEF DESCRIPTION OF THE DRAWINGS

FIG. 1 is a diagram schematically illustrating a configuration of a process furnace of a substrate processing apparatus according to one or more embodiments of the present disclosure.

FIG. 2A is a diagram schematically illustrating a plan view of a reaction tube provided with a protrusion side wall heater according to the embodiments of present disclosure, FIG. 2B is a diagram schematically illustrating a front view of the reaction tube provided with the protrusion side wall heater according to the embodiments of present disclosure, and FIG. 2C is a diagram schematically illustrating a side view (which is commonly applied to both left and right sides) of the reaction tube provided with the protrusion side wall heater according to the embodiments of present disclosure.

FIG. 3A is a diagram schematically illustrating a top view of a reaction vessel using the reaction tube according to the embodiments of present disclosure, and FIG. 3B is a diagram schematically illustrating a cross-section of the reaction vessel using the reaction tube according to the embodiments of present disclosure.

FIG. 4A is a diagram schematically illustrating a plan view of a heater configured to heat a substrate in the reaction tube according to the embodiments of present disclosure, FIG. 4B is a diagram schematically illustrating a front view of the heater configured to heat the substrate in the reaction tube according to the embodiments of present disclosure, and FIG. 4C is a diagram schematically illustrating a side view (which is commonly applied to both left and right sides) of the heater configured to heat the substrate in the reaction tube according to the embodiments of present disclosure.

FIG. 5 is a diagram schematically illustrating a cross-section taken along a line A-A of the heater (which is shown in FIGS. 4A through 4C) according to the embodiments of present disclosure.

FIG. 6 is a diagram schematically illustrating a cross-section taken along a line B-B of the heater (which is shown in FIGS. 4A through 4C) according to the embodiments of present disclosure.

FIG. 7 is a diagram schematically illustrating a cross-section of the process furnace in which the reaction tube is incorporated in the heater according to the embodiments of present disclosure.

FIG. 8 is a block diagram schematically illustrating configuration of a controller configured to operate (control) each component of the substrate processing apparatus according to the embodiments of the present disclosure.

FIG. 9 is a flow chart schematically illustrating a process flow of a manufacturing process of a semiconductor device according to the embodiments of the present disclosure.

FIG. 10A is a diagram schematically illustrating a first gas supplier according to the embodiments of the present disclosure, and FIG. 10B is a diagram schematically illustrating a second gas supplier according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail mainly with reference to the drawings. For example, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

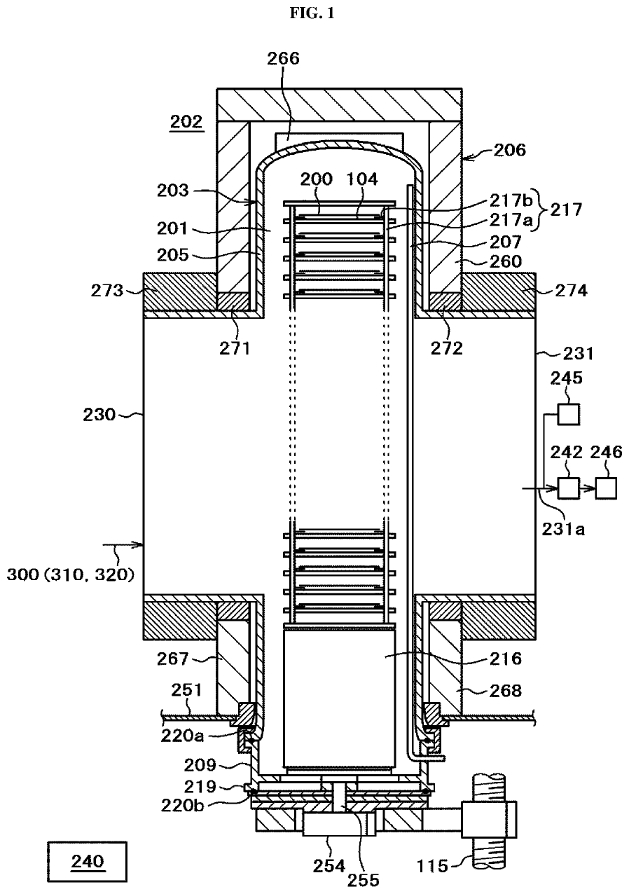

A process furnace 202 of a substrate processing apparatus preferably used in the embodiments of the present disclosure will be described with reference to FIGS. 1 through 7.

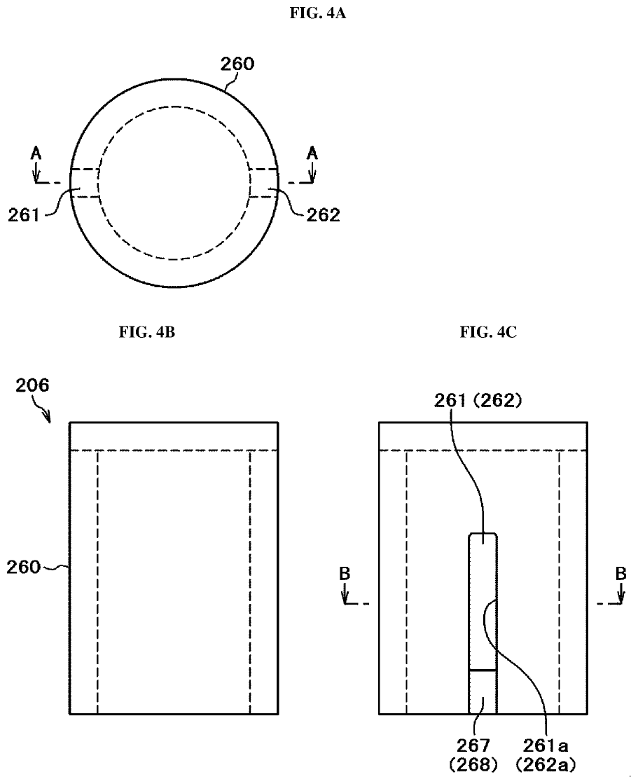

The process furnace 202 includes a heater 206 serving as a first heater (which is a first heating structure or a first heating apparatus). The heater 206 is of a cylindrical shape, and is vertically installed while being supported by a heater base 251 serving as a support plate. The heater 206 includes a heat insulator 260 of a cylindrical shape. An inlet port 261 (see FIGS. 4A and 4C) is provided on a side surface of the heat insulator 260 of the heater 206 so as to prevent contacting a gas introduction pipe 230 serving as a gas supply side protrusion. In addition, an outlet port 262 (see FIGS. 4A and 4C) is provided so as to prevent contacting a gas exhaust pipe 231 serving as a gas exhaust side protrusion.

Further, as will be described later, a heater wire 266 is provided in an inner side of the heater 206. In addition, an auxiliary heater (also referred to as a “second heater” which is a second heating structure or a second heating apparatus) 271 for the gas introduction pipe 230 is provided between the heat insulator 260 and the gas introduction pipe 230 at the inlet port 261 of the heat insulator 260. The auxiliary heater 271 may also be referred to as the “second heater 271”. In addition, an auxiliary heater (also referred to as a “third heater” which is a third heating structure or a third heating apparatus) 272 for the gas exhaust pipe 231 is provided between the heat insulator 260 and the gas exhaust pipe 231 at the outlet port 262 of the heat insulator 260. For example, a heat insulator 273 is provided in contact with the gas introduction pipe 230, and a heat insulator 274 is provided in contact with the gas exhaust pipe 231.

A reaction tube 203 is provided in the inner side of the heater 206 serving as the first heater to be aligned in a manner concentric with the heater 206. For example, the reaction tube 203 is made of a heat resistant material such as quartz (SiO₂) and silicon carbide (SIC). For example, the reaction tube 203 is of a cylindrical shape with a closed upper end and an open lower end. A process chamber 201 is provided in a hollow cylindrical portion of the reaction tube 203. The process chamber 201 is configured to be capable of accommodating a plurality of substrates including a substrate 200 such as a semiconductor wafer by using a boat 217 described later. Hereinafter, the plurality of substrates including the substrate 200 may also be simply referred to as “substrates 200”. The substrates 200 are accommodated (or supported) in a multistage manner in a vertical direction in the boat 217 while the substrates 200 are horizontally oriented.

A manifold 209 is provided under the reaction tube 203 to be aligned in a manner concentric with the reaction tube 203. For example, the manifold 209 is made of a material such as stainless steel (SUS). For example, the manifold 209 is of a cylindrical shape with open upper and lower ends. The manifold 209 is engaged with the reaction tube 203 so as to support the reaction tube 203. An O-ring 220a serving as a seal is provided between the manifold 209 and the reaction tube 203. The reaction tube 203 is installed vertically while the manifold 209 is supported by the heater base 251. A reaction vessel 204 is constituted mainly by the reaction tube 203 and the manifold 209.

A gas supplier (which is a gas supply structure or a gas supply system) 300 is connected to a side surface of the reaction tube 203. The gas supplier 300 is configured to supply a gas to the process chamber 201 through the gas introduction pipe 230. The gas supplier 300 includes a first gas supplier (which is a first gas supply structure or a first gas supply system) 310 and a second gas supplier (which is a second gas supply structure or a second gas supply system) 320.

In the first gas supplier 310, as shown in FIG. 10A, a first gas supply source 312, a mass flow controller (MFC) serving as a flow rate controller (flow rate control structure) 313 and a valve 314 serving as an opening/closing valve are sequentially installed at a gas supply pipe 311 in this order from an upstream side to a downstream side of the gas supply pipe 311 in a gas flow direction.

The first gas supply source 312 is a source of a first gas (also referred to as a “first element-containing gas”) containing a first element. The first element-containing gas serves as a source gas, which is one of process gases. According to the present embodiments, for example, the first element is silicon (Si). More specifically, a chlorosilane source gas containing a silicon-chlorine bond (Si—Cl bond) such as hexachlorodisilane (Si₂Cl₆, abbreviated as HCDS) gas, monochlorosilane (SiH₃Cl, abbreviated as MCS) gas, dichlorosilane (SiH₂Cl₂, abbreviated as DCS) gas, trichlorosilane (SiHCl₃, abbreviated as TCS) gas, tetrachlorosilane (SiCl₄, abbreviated as STC) gas and octachlorotrisilane (Si₃Cl₈, abbreviated as OCTS) gas may be used as the first element-containing gas.

The first gas supplier 310 is constituted mainly by the gas supply pipe 311, the MFC 313 and the valve 314. The first gas supplier 310 may also be referred to as a “silicon-containing gas supplier” (which is a silicon-containing gas supply structure or a silicon-containing gas supply system).

A gas supply pipe 315 is connected to the gas supply pipe 311 at a downstream side of the valve 314. An inert gas supply source 316, a mass flow controller (MFC) 317 and a valve 318 serving as an opening/closing valve are sequentially installed at the gas supply pipe 315 in this order from an upstream side toward a downstream side of the gas supply pipe 315 in the gas flow direction. For example, the inert gas such as nitrogen (N₂) gas is supplied from the inert gas supply source 316.

A first inert gas supplier (which is a first inert gas supply structure or a first inert gas supply system) is constituted mainly by the gas supply pipe 315, the MFC 317 and the valve 318. The inert gas supplied from the inert gas supply source 316 is used as a purge gas for purging the gas remaining in the reaction tube 203 during a substrate processing described later. The first gas supplier 310 may further include the first inert gas supplier.

In the second gas supplier 320, as shown in FIG. 10B, a second gas supply source 322, a mass flow controller (MFC) serving as a flow rate controller (flow rate control structure) 323 and a valve 324 serving as an opening/closing valve are sequentially installed at a gas supply pipe 321 in this order from an upstream side to a downstream side of the gas supply pipe 321 in the gas flow direction.

The second gas supply source 322 is a source of a second gas (also referred to as a “second element-containing gas”) containing a second element. The second element-containing gas serves as one of the process gases. Further, the second element-containing gas may serve as a reactive gas or a modification gas. Hereinafter, the first gas and the second gas may be collectively or individually referred to as a “process gas.”

According to the present embodiments, for example, the second element-containing gas contains the second element different from the first element. As the second element, for example, one of oxygen (O), nitrogen (N) and carbon (C) may be used. According to the present embodiments, for example, a nitrogen-containing gas is used as the second element-containing gas. More specifically, a hydrogen nitride-based gas containing a nitrogen-hydrogen bond (N—H bond) such as ammonia (NH₃), diazene (N₂H₂) gas, hydrazine (N₂H₄) gas and N₃H₈ gas may be used as the second element-containing gas.

The second gas supplier 320 is constituted mainly by the gas supply pipe 321, the MFC 323 and the valve 324.

A gas supply pipe 325 is connected to the gas supply pipe 321 at a downstream side of the valve 324. An inert gas supply source 326, a mass flow controller (MFC) 327 and a valve 328 serving as an opening/closing valve are sequentially installed at the gas supply pipe 325 in this order from an upstream side toward a downstream side of the gas supply pipe 325 in the gas flow direction. For example, the inert gas such as nitrogen (N₂) gas is supplied from the inert gas supply source 326.

A second inert gas supplier (which is a second inert gas supply structure or a second inert gas supply system) is constituted mainly by the gas supply pipe 325, the MFC 327 and the valve 328. The inert gas supplied from the inert gas supply source 326 is used as the purge gas for purging the gas remaining in the process chamber 201 during the substrate processing described later. The second gas supplier 320 may further include the second inert gas supplier.

In the present embodiments, the first gas supplier 310 and the second gas supplier 320 may be collectively or individually referred to as a “gas supplier”. While the present embodiments will be described by way of an example in which the two gas suppliers (that is, the first gas supplier 310 and the second gas supplier 320) are used, the present embodiments are not limited thereto. For example, one gas supplier or three or more gas suppliers may be used depending on contents of the substrate processing.

The gas exhaust pipe 231 through which an inner atmosphere of the process chamber 201 is exhausted is provided on a side surface of the reaction tube 203 at a location opposite to a connection location where the gas introduction pipe 230 is connected to the reaction tube 203. A gas exhaust line 231a is connected to the gas exhaust pipe 231 at a downstream side (which is a location opposite to a connection location where the gas exhaust pipe 231 is connected to the reaction tube 203) of the gas exhaust pipe 231 through a connector including a seal. A vacuum exhaust apparatus 246 such as a vacuum pump is connected to the gas exhaust line 231a through a pressure sensor 245 and a pressure regulator (which is a pressure adjusting apparatus) 242. The vacuum exhaust apparatus 246 is configured to be capable of vacuum-exhausting the inner atmosphere of the process chamber 201 such that an inner pressure of the process chamber 201 reaches and is maintained at a predetermined pressure (vacuum degree). The pressure regulator 242 is configured such that the inner pressure of the process chamber 201 is controlled (adjusted) to a predetermined pressure at a predetermined timing based on a pressure detected by the pressure sensor 245.

Similar to the reaction tube 203, each of the gas introduction pipe 230 and the gas exhaust pipe 231 provided at the reaction tube 203 is made of a heat resistant material such as quartz and silicon carbide.

The gas introduction pipe 230 is configured such that the gas is supplied into the process chamber 201 through the gas introduction pipe 230. Therefore, the gas introduction pipe 230 is disposed at a gas supply side when viewed from the process chamber 201. In addition, the gas exhaust pipe 231 is configured such that the gas (exhaust gas) is exhausted from the process chamber 201 through the gas exhaust pipe 231. Therefore, the gas exhaust pipe 231 is disposed at a gas exhaust side when viewed from the process chamber 201. Further, in the present embodiments, the gas supply side protrusion and the gas exhaust side protrusion may be collectively or individually referred to as a “protrusion.”

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as stainless steel (SUS), and is of a disk shape. An O-ring 220b serving as a seal is provided on an upper surface of the seal cap 219 so as to be in contact with the lower end of the manifold 209. A rotator 254 configured to rotate the boat 217 is provided at the seal cap 219 in a manner opposite to the process chamber 201. A rotating shaft 255 of the rotator 254 is connected to the boat 217 described later through the seal cap 219. As the rotator 254 rotates the boat 217, the substrates 200 are rotated. The seal cap 219 may be elevated or lowered in the vertical direction by a boat elevator 115 serving as an elevating structure vertically provided outside the reaction tube 203. When the seal cap 219 is elevated or lowered in the vertical direction by the boat elevator 115, the boat 217 may be transferred (loaded) into the process chamber 201 or transferred (unloaded) out of the process chamber 201. The rotator 254 and the boat elevator 115 are controlled at a predetermined timing to perform a predetermined operation.

The boat 217 serving as a substrate retainer is supported by the rotating shaft 255 through a heat insulator 216. For example, the boat 217 is constituted by: a plurality of support columns 217a standing vertically; a plurality of disks 104 supported by the support columns 217a, respectively, at regular intervals; and a plurality of substrate support structures 217b supported by the support columns 217a, respectively, between the disks 104. In the boat 217, the substrates 200 are vertically arranged and supported in a multistage manner by placing the substrates 200 on the substrate support structures 217b attached to the support columns 217a, respectively, in spaces partitioned by the disks 104. For example, the substrates 200 are supported in the boat 217 while the substrates 200 are horizontally oriented with their centers aligned with one another. For example, the substrates 200 are arranged at regular intervals in the boat 217. For example, the boat 217 is made of a heat resistant material such as quartz and silicon carbide. A substrate retaining structure is constituted by the heat insulator 216 and the boat 217. When the substrates 200 are processed, the boat 217 is accommodated in the reaction tube 203. For example, the boat 217 may be configured to be capable of supporting about 5 substrates to 50 substrates as the substrates 200. In addition, the disks 104 may also be referred to as “separators”.

The heat insulator 216 is configured such that a conduction or transmission of a heat tends to be reduced in the vertical direction. In addition, a cavity may be provided in the heat insulator 216. For example, a hole may be provided on a lower surface of the heat insulator 216. By providing the hole, it is possible to prevent a pressure difference from occurring between an inside and an outside of the heat insulator 216, and it is also possible to prevent a wall of the heat insulator 216 from thickening. In addition, a cap heater (not shown) may be provided in the heat insulator 216.

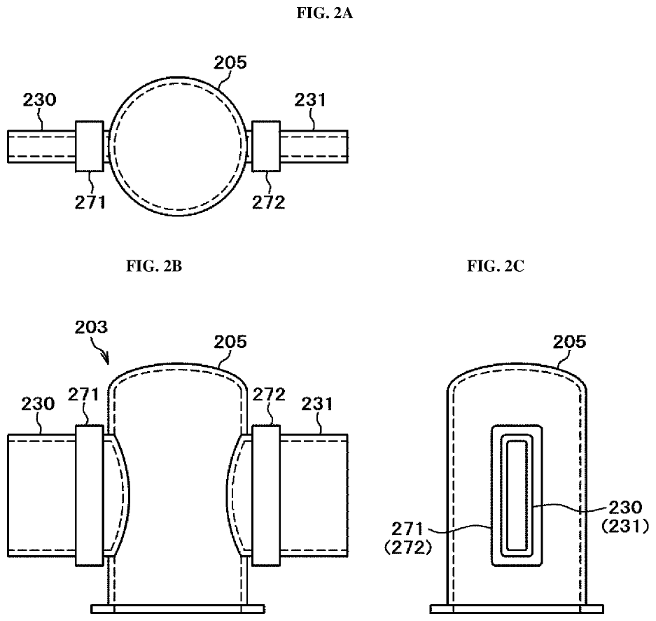

The reaction tube 203 will be described in detail with reference to FIGS. 2A, 2B and 2C. A cross-section of each of the gas introduction pipe 230 and the gas exhaust pipe 231 is of an appropriate shape. However, for example, each of the gas introduction pipe 230 and the gas exhaust pipe 231 is of a flat rectangular parallelepiped shape with a hollow portion provided therein. The gas introduction pipe 230 and the gas exhaust pipe 231 are provided symmetrically on a side surface of a body structure 205 (which is vertically erected) with their flat surfaces facing a horizontal direction. For example, A position (or positions) at the side surface of the body structure 205 where the gas introduction pipe 230 and the gas exhaust pipe 231 are provided may be a central position on the side surface of the body structure 205 and also an intermediate position in a height direction, and a position (or positions) facing the substrate 200 or an entirety of or a part of the substrates 200 to be processed inside the body structure 205. The gas introduction pipe 230 and the gas exhaust pipe 231 are connected horizontally to the body structure 205. The gas introduction pipe 230 and the gas exhaust pipe 231 are welded and connected to the body structure 205 such that pipe axes thereof are aligned on a straight line.

The auxiliary heater 271 for the gas introduction pipe 230 is provided at a first end (which is adjacent to the body structure 205) of the gas introduction pipe 230 so as to be in contact with and cover the gas introduction pipe 230 (on both side surfaces, an upper surface and a lower surface). The auxiliary heater 272 for the gas exhaust pipe 231 is provided at a first end (which is adjacent to the body structure 205) of the gas exhaust pipe 231 so as to be in contact with and cover the gas exhaust pipe 231 (on both side surfaces, an upper surface and a lower surface). Since upper and lower portions of each of the gas introduction pipe 230 and the gas exhaust pipe 231 tend to be cooled easily, by covering at least the upper and lower surfaces of the gas introduction pipe 230 and the upper and lower surfaces of the gas exhaust pipe 231 with the auxiliary heaters 271 and 272, respectively, it is possible to suppress a heat escape.

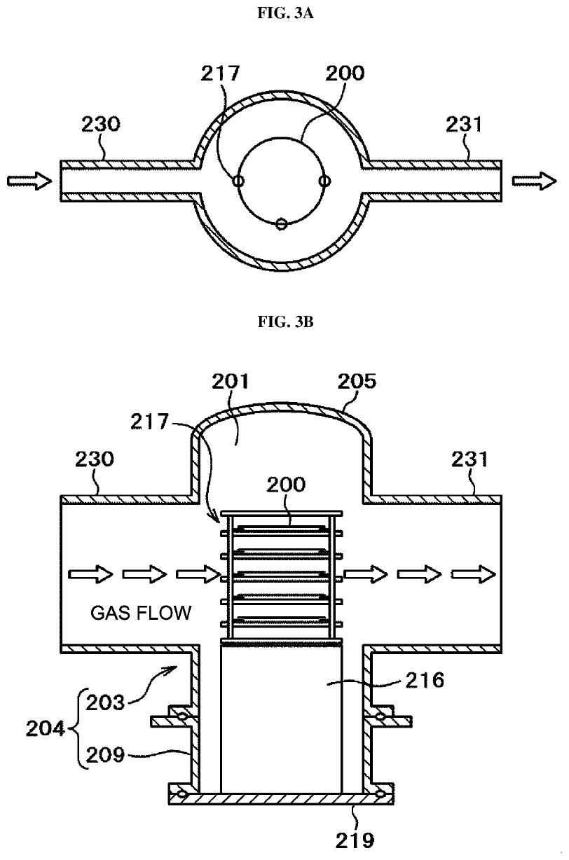

A gas flow inside the reaction vessel 204 will be described with reference to FIGS. 3A and 3B. As described above, the reaction vessel 204 is constituted by the reaction tube 203 and the manifold 209. For example, the manifold 209 is of a cylindrical shape with open upper and lower ends. The manifold 209 is engaged with a lower end of the reaction tube 203 so as to support the reaction tube 203. The process chamber 201 in which the substrates 200 are processed is provided in the reaction vessel 204.

The boat 217 serving as the substrate retainer and accommodating (supporting) the substrates 200 in a multistage manner in the vertical direction is inserted into the process chamber 201. The lower end opening of the manifold 209 is airtightly closed (scaled) by the seal cap 219 configured to support the boat 217 inserted into the process chamber 201.

By exhausting the process gas (which is introduced through the gas introduction pipe 230 of the reaction tube 203) through the gas exhaust pipe 231, it is possible to provide a flow of the gas (that is, a gas flow) in the process chamber 201 as a “side flow” as shown by white arrows in FIG. 3B. Thereby, it is possible to supply the process gas to the substrates 200 in the horizontal direction and it is also possible to exhaust the process gas from the substrates 200 in the horizontal direction. As a result, it is possible to smoothly supply the process gas between the substrates 200. Therefore, the position (or the positions) at the side surface of the body structure 205 where the gas introduction pipe 230 and the gas exhaust pipe 231 are provided may not be the intermediate position in the height direction. It is preferable that the position (or the positions) at the side surface of the body structure 205 where the gas introduction pipe 230 and the gas exhaust pipe 231 are provided may be a position (or positions) facing at least an entirety of a substrate processing area (substrate processing region). For example, a product substrate (or product substrates) may be arranged between an upper end and a lower end of the gas introduction pipe 230 in the height direction. According to the present embodiments, even when side dummy substrates placed on an upper end and a lower end of the boat 217 and the product substrate (or the product substrates) are processed in the process chamber 201, the substrate processing area may refer to a product substrate processing area where the product substrate (or the product substrates) alone is (or are) processed.

A configuration of the heater 206 will be described in detail with reference to FIGS. 4A, 4B and 4C. As described above, the heater 206 includes: the heat insulator 260 of a cylindrical shape with a closed upper portion and an open lower portion; the inlet port 261 provided at the heat insulator 260 to prevent contacting an interference or contact with the gas introduction pipe 230; and the outlet port 262 provided at the heat insulator 260 opposite to the inlet port 261 to prevent contacting the gas introduction pipe 230.

Specifically, for example, the inlet port 261 provided at the heat insulator 260 to prevent contacting the gas introduction pipe 230 may be configured by a notch 261a of a groove shape extending in a straight line from a lower end of the heat insulator 260 to above a center of the heat insulator 260. For example, a width of the notch 261a is set to be wider than a total thickness of a thickness of the gas introduction pipe 230 of the flat rectangular parallelepiped shape and a thickness of the auxiliary heater 271. For example, similar to the inlet port 261, the outlet port 262 provided at the heat insulator 260 to prevent contacting the gas exhaust pipe 231 may be configured by a notch 262a of a groove shape extending in a straight line from the lower end of the heat insulator 260 to above the center of the heat insulator 260. For example, a width of the notch 262a is set to be wider than a total thickness of a thickness of the gas exhaust pipe 231 of the flat rectangular parallelepiped shape and a thickness of the auxiliary heater 272. Thereby, when the heater 206 covers the reaction tube 203 from above the reaction tube 203, it is possible to cover an outer periphery of the reaction tube 203 while avoiding the interference with, for example, the gas introduction pipe 230 of the flat rectangular parallelepiped shape and the gas exhaust pipe 231 of the flat rectangular parallelepiped shape.

After the heater 206 covers the reaction tube 203, a heat insulator 267 is attached to close the inlet port 261 provided at the lower portion of the gas introduction pipe 230. In addition, a heat insulator 268 is attached to close the outlet port 262 provided at the lower portion of the gas exhaust pipe 231. The auxiliary heaters 271 and 272 may be attached instead of the heat insulators 267 and 268.

For example, the width of each of the notches 261a and 262a is preferably set to be smaller than a diameter of the reaction tube 203, and more preferably set to be smaller than a diameter of the substrate 200 to be processed in the reaction tube 203.

For example, preferably, a width of each of the gas introduction pipe 230 and the gas exhaust pipe 231 is set such that the width in the horizontal direction with respect to a substrate processing surface is equal to or less than a half (½) of the diameter of the substrate 200. Thereby, it is advantageous in that the gas flowing out from the gas introduction pipe 230 can pass through the center of the substrate 200 and flow to the gas exhaust pipe 231 while preventing a drop in a flow velocity of the gas. More preferably, the width of each of the gas introduction pipe 230 and the gas exhaust pipe 231 is set such that the width in the horizontal direction with respect to the substrate processing surface is equal to or less than a third (⅓) of the diameter of the substrate 200. Thereby, it is advantageous in that the gas flowing out from the gas introduction pipe 230 can pass through the center of the substrate 200 and flow to the gas exhaust pipe 231 while more reliably preventing a drop in the flow velocity of the gas. Still more preferably, the width of each of the gas introduction pipe 230 and the gas exhaust pipe 231 is set such that the width in the horizontal direction with respect to the substrate processing surface is equal to or less than one-fifteenth ( 1/15) of the diameter of the substrate 200. Thereby, it is more advantageous in that the gas flowing out from the gas introduction pipe 230 can pass through the center of the substrate 200 and flow to the gas exhaust pipe 231 while still more reliably preventing a drop in the flow velocity of the gas. It is preferable to set (determine) the width of each of the notches 261a and 262a in accordance with the width of each of the gas introduction pipe 230 and the gas exhaust pipe 231. Preferably, the widths described above are set to avoid adverse thermal effects on the outside even when the heat is radiated from between the notch 261a and the gas introduction pipe 230 or between the notch 262a and the gas exhaust pipe 231.

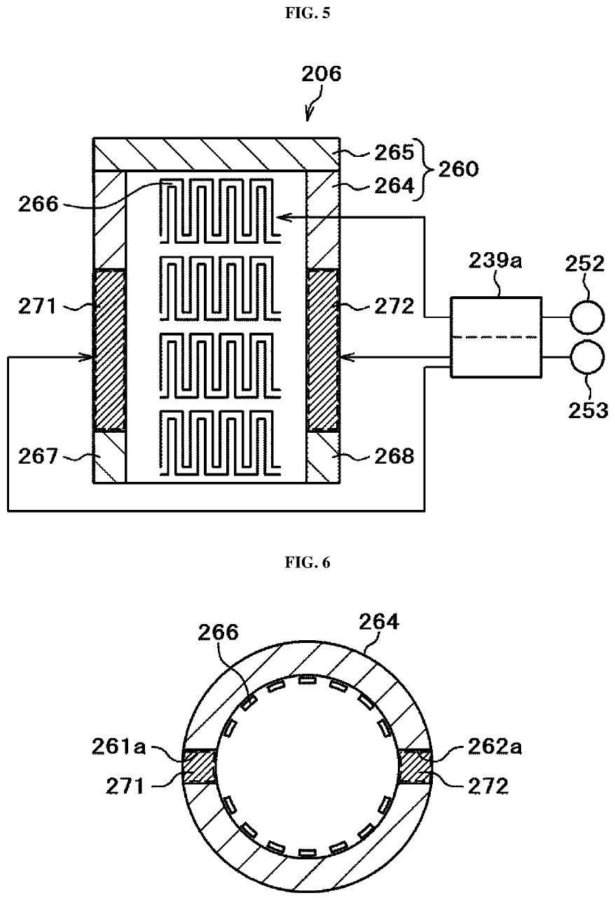

An inner structure of the heater 206 will be described with reference to FIGS. 5 and 6. The heat insulator 260 of the heater 206 is constituted by: a side wall heat insulator 264 of a cylindrical shape; and a ceiling heat insulator 265 of a circular shape configured to close an upper portion of the side wall heat insulator 264. The heater wire 266 is provided in an inner side (which is adjacent to the reaction tube 203) of the heat insulator 260. The heater wire 266 is provided in a zigzag shape in the vertical direction. Similar to a conventional case, the heater wire 266 is divided into zones (as illustrated in FIG. 5, divided into four zones) in the vertical direction, and is provided in an annular shape along an inner wall of the side wall heat insulator 264 corresponding to each zone.

For example, the auxiliary heater 271 for the gas introduction pipe 230 is provided between the notch 261a and the gas introduction pipe 230 so as to be wrapped (or wound) around the gas introduction pipe 230. The auxiliary heater 271 for the gas introduction pipe 230 is provided along an inner side wall of the notch 261a. For example, the auxiliary heater 272 for the gas exhaust pipe 231 is provided between the notch 262a and the gas exhaust pipe 231 so as to be wrapped around the gas exhaust pipe 231. The auxiliary heater 272 for the gas exhaust pipe 231 is provided along an inner side wall of the notch 262a. Each of the auxiliary heaters 271 and 272 are made of a heat insulating cloth. For example, each of the auxiliary heaters 271 and 272 is provided with a heater wire (not shown) and a temperature sensor (or temperature sensors) accommodated in an insulating tube placed in the vicinity of the heater wire (not shown). The temperature sensor (or the temperature sensors) may be attached at least at one location, preferably at three locations at the top, middle and bottom of each of the auxiliary heaters 271 and 272. When the temperature sensors are provided at a plurality of locations, by switching and measuring the temperature, it is possible to measure a temperature of the gas introduction pipe 230 more accurately. As a result, it is possible to perform a temperature control more accurately.

By providing the auxiliary heaters 271 and 272 in a manner described above, the auxiliary heaters 271 and 272 are provided across the each divided zone of the heater wire 266. A power supply 253 configured to supply an electric power to the auxiliary heaters 271 and 272 through a power control circuit 239a is provided separately from a power supply 252 configured to supply an electric power to the heater wire 266.

The heat insulators 273 and 274 will be described with reference to FIG. 1. The auxiliary heaters 271 and 272 are attached to the gas introduction pipe 230 and the gas exhaust pipe 231, respectively, and the reaction tube 203 is covered with the heat insulator 260. Then, after the heat insulators 267 and 268 are attached, the heat insulator 273 is wrapped around the gas introduction pipe 230. Further, the heat insulator 274 is wrapped around the gas exhaust pipe 231. Thereby, it is possible to suppress a heat radiation from the gas introduction pipe 230, the gas exhaust pipe 231, and the heater 206.

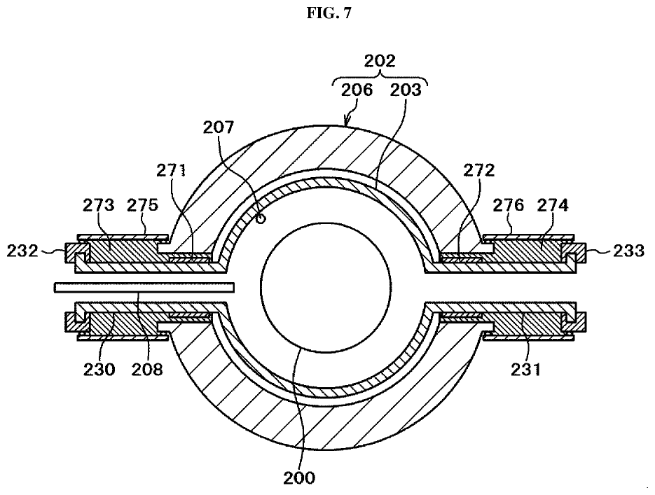

Temperature sensors will be described using FIG. 7. A temperature sensor 207 serving as a temperature detector is provided between the heater 206 and the reaction tube 203 in a direction perpendicular to the heater base 251. By adjusting a state of an electrical conduction to the heater wire 266 based on temperature information detected by the temperature sensor 207, a distribution of an inner temperature of the process chamber 201 is controlled (adjusted) to a predetermined temperature distribution at a predetermined timing.

In addition, a temperature sensor 208 is provided to measure a temperature between an ejection port of the gas introduction pipe 230 and the substrate 200. The temperature sensor 208 is provided along the flow of the gas ejected from the gas introduction pipe 230 into the reaction tube 203 to the gas exhaust pipe 231. When the heater 206 is divided into N components (wherein N is an integer equal to or greater than 2), it is preferable to arrange the temperature sensors 208 at N locations in the vertical direction corresponding to the heater 206 divided into N components.

By adjusting a state of the electrical conduction to the auxiliary heater 271 for the gas introduction pipe 230 based on the temperature information detected by the temperature sensor 208 and a temperature sensor provided in the auxiliary heater 271 for the gas introduction pipe 230, an inner temperature of the gas introduction pipe 230 is controlled (adjusted) to a predetermined temperature at a predetermined timing.

By adjusting a state of the electrical conduction to the auxiliary heater 272 for the gas exhaust pipe 231 based on temperature information detected by a temperature sensor provided in the auxiliary heater 272 for the gas exhaust pipe 231, an inner temperature of the gas exhaust pipe 231 is controlled (adjusted) to a predetermined temperature at a predetermined timing.

For example, the heater wire 266, the auxiliary heater 271 for the gas introduction pipe 230, and the auxiliary heater 272 for the gas exhaust pipe 231 (which are described above) are controlled by separate systems, respectively.

With such a configuration described above, by performing the temperature control at a position spaced apart from the heater wire 266 and from the auxiliary heaters 271 and 272, which is likely to be a cold spot (for example, at a position located on an extension line of a center line of the gas introduction pipe 230 and located closer to the substrate 200 than the ejection port of the gas introduction pipe 230), it is possible to eliminate the cold spot. Further, with respect to the gas introduction pipe 230, by performing a sufficient preheating, it is possible to reduce a temperature deviation in the gas introduction pipe 230. In addition, with respect to the gas exhaust pipe 231, it is possible to increase a temperature of an inner wall of the gas exhaust pipe 231. As a result, it is possible to prevent by-products from adhering to the gas exhaust pipe 231.

Another embodiment of the heat insulators will be described with reference to FIG. 7. For example, covers 275 and 276 may be provided to block and seal a gap between an outer side wall of the heater 206 and the gas introduction pipe 230 and a gap between the outer side wall of the heater 206 and gas exhaust pipe 231 from outside air, respectively. Further, spaces defined by the covers 275 and 276, the heater 206, the gas introduction pipe 230 and the gas exhaust pipe 231 are filled with the heat insulators 273 and 274. The cover 275 is connected to a flange 232 provided on the gas introduction pipe 230 and an outer wall of the heater 206. The cover 276 is connected to a flange 233 provided on the gas exhaust pipe 231 and the outer wall of the heater 206.

By blocking and covering the gap between the outer side wall of the heater 206 and the gas introduction pipe 230 and the gap between the outer side wall of the heater 206 and gas exhaust pipe 231 from the outside air by using the covers 275 and 276 so as to suppress a convection with the outside air, it is possible to eliminate a distorted temperature distribution generated by the convection. In addition, even when structural conditions of the gaps described above change due to repeated attachment and detachment of the reaction tube 203, since the convection is suppressed, the conditions of the gaps are not affected by the convection.

By filling the spaces defined by the covers 275 and 276, the heater 206, the gas introduction pipe 230 and the gas exhaust pipe 231 with the heat insulators 273 and 274, it is possible to suppress the convection of the gas in the spaces described above, and it is also possible to suppress the heat radiation from the gas introduction pipe 230, the gas exhaust pipe 231 and the auxiliary heaters 271 and 272. Thereby, it is possible to suppress temperature elevations of the covers 275 and 276, and it is also possible to maintain airtightness related thereto. As a result, it is possible to improve a temperature control performance of the reaction tube 203 by the auxiliary heaters 271 and 272 while preventing adverse effects of thermal disturbances.

Even in an environment where a fluctuation in a control of the heater 206 affects a temperature of the reaction tube 203 (which is an object to be heated), the auxiliary heaters 271 and 272 together with the temperature sensor used for the temperature control are closely provided to the reaction tube 203. Thus, the auxiliary heaters 271 and 272 follow a temperature change of the reaction tube 203 with little delay. As a result, it is possible to perform the temperature control with a sufficient responsiveness.

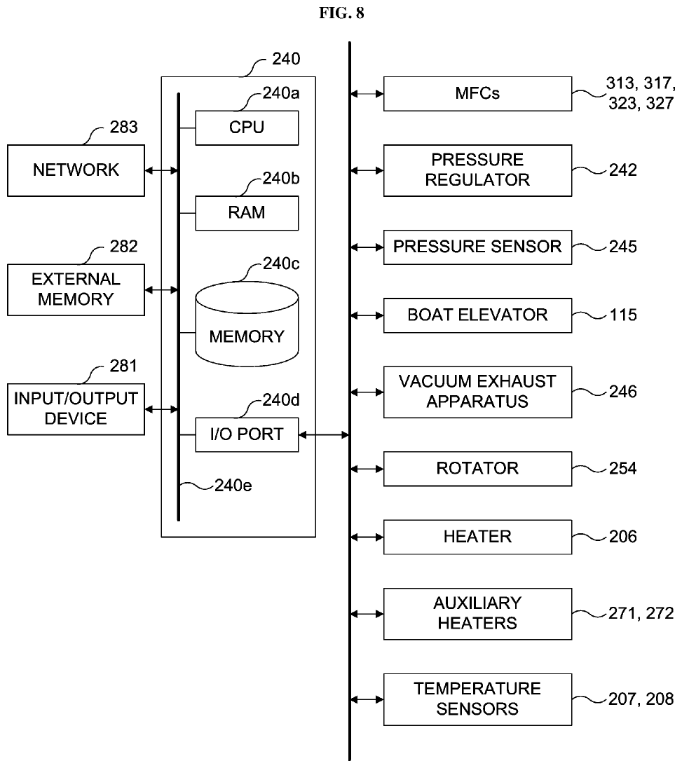

A configuration of a controller 240 will be described with reference to FIG. 8. The controller 240 serving as a control structure (control apparatus) is constituted by a computer including a CPU (Central Processing Unit) 240a, a RAM (Random Access Memory) 240b, a memory 240c and an I/O port 240d. The RAM 240b, the memory 240c and the I/O port 240d may exchange data with the CPU 240a through an internal bus 240c. For example, an input/output device 281 constituted by a component such as a touch panel and an external memory 282 may be connected to the controller 240.

For example, the memory 240c is constituted by components such as a flash memory and a hard disk drive (HDD). For example, a control program configured to control an operation of the substrate processing apparatus and a process recipe containing information on sequences and conditions of the substrate processing described later may be readably stored in the memory 240c. The process recipe is obtained by combining steps of the substrate processing described later such that the controller 240 can execute the steps to acquire a predetermined result, and functions as a program. Hereafter, the process recipe and the control program may be collectively or individually referred to as a “program.” Thus, in the present specification, the term “program” may refer to the process recipe alone, may refer to the control program alone, or may refer to both of the process recipe and the control program. The RAM 240b functions as a memory area (work area) where a program or data read by the CPU 240a is temporarily stored.

The I/O port 240d is electrically connected to components such as the MFCs 313, 317, 323 and 327, the pressure regulator 242, the pressure sensor 245, the vacuum exhaust apparatus 246, the heater 206, the auxiliary heaters 271 and 272, the temperature sensors 207 and 208, the rotator 254 and the boat elevator 115. For example, in the present specification, “electrically connected” means that the components are connected by physical cables or the components are capable of communicating with one another to transmit and receive signals (electronic data) to and from one another directly or indirectly. For example, a device for relaying the signals or a device for converting or computing the signals may be provided between the components.

The CPU 240a is configured to read the control program from the memory 240c and execute the read control program. In addition, the CPU 240a is configured to read the process recipe from the memory 240c in accordance with an operation command inputted from the input/output device 281. In accordance with the contents of the read process recipe, the CPU 240a may be configured to control various operations such as a control operation of the rotator 254, flow rate adjusting operations for various gases by the MFCs 313, 317, 323 and 327, an opening and closing operation of the pressure regulator 242, a pressure adjusting operation by the pressure regulator 242 based on the pressure sensor 245, a start and stop of the vacuum exhaust apparatus 246, a temperature adjusting operation by the heater 206 based on the temperature sensor 207, a temperature adjusting operation by the auxiliary heater 271 based on the temperature sensor 208 or the like, operations of adjusting a forward rotation and a reverse rotation, a rotation angle and a rotation speed of the boat 217 by the rotator 254, and an elevating and lowering operation of the boat 217 by the boat elevator 115.

The controller 240 is not limited to a dedicated computer, and may be embodied by a general-purpose computer. For example, the controller 240 according to the present embodiments may be embodied by preparing the external memory 282 (e.g., a magnetic tape, a magnetic disk such as a flexible disk and a hard disk, an optical disk such as a CD and a DVD, a magneto-optical disk such as an MO, a semiconductor memory such as a USB memory and a memory card) in which the above-described program is stored, and by installing the program onto the general-purpose computer using the external memory 282. A method of providing the program to the computer (general-purpose computer) is not limited to the external memory 282. For example, the program may be directly provided to the computer by a communication instrument such as a network 283 (Internet and a dedicated line) instead of the external memory 282. The memory 240c and the external memory 282 may be embodied by a non-transitory computer-readable recording medium. Hereinafter, the memory 240c and the external memory 282 are collectively or individually referred to as a recording medium. In the present specification, the term “recording medium” may refer to the memory 240c alone, may refer to the external memory 282 alone, or may refer to both of the memory 240c and the external memory 282.

### (2) Substrate Processing

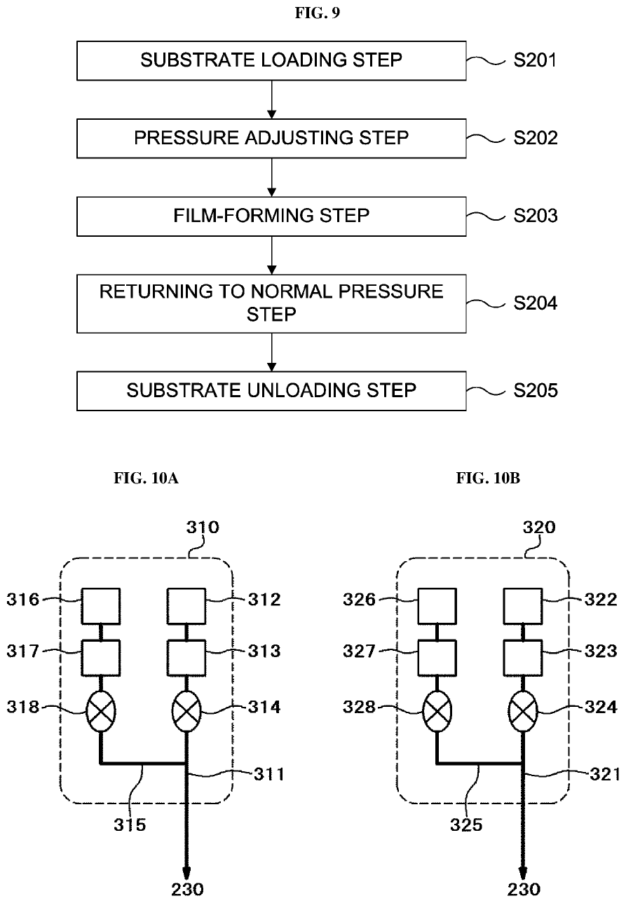

Hereinafter, the substrate processing (film-forming process) of forming a film on the substrate 200, which is a part of a manufacturing process of a semiconductor device, by using the substrate processing apparatus described above will be described with reference to FIG. 9. For example, as the film, a silicon nitride film (Si₃N₄ film) (which serves as an insulating film and a silicon-containing film) is formed on the substrate 200. In the following description, operations of the components constituting the substrate processing apparatus are controlled by the controller 240.

### <Substrate Loading Step S201>

A substrate loading step S201 will be described. After the substrates 200 are charged into the boat 217 (substrate charging step), as shown in FIG. 1, the boat 217 charged with the substrates 200 is elevated by the boat elevator 115 and loaded (or transferred) into the process chamber 201 (boat loading step). With the boat 217 loaded, the seal cap 219 seals the lower end of the manifold 209 via the O-ring 220b.

### <Pressure Adjusting Step S202>

A pressure adjusting step S202 will be described. In the present step, the inner pressure of the process chamber 201 is adjusted to a predetermined pressure (vacuum degree) by the vacuum exhaust apparatus 246. When adjusting the inner pressure of the process chamber 201, the inner pressure of the process chamber 201 is measured by the pressure sensor 245, and the pressure regulator 242 is feedback-controlled based on the pressure measured by the pressure sensor 245. In addition, the process chamber 201 is heated by the heater wire 266 based on temperature information detected by the temperature sensor 207 such that the inner temperature of the process chamber 201 reaches and is maintained at a predetermined temperature. In addition, the gas introduction pipe 230 is heated by the auxiliary heater 271 for the gas introduction pipe 230 based on the temperature information detected by the temperature sensor 208 such that the inner temperature of the gas introduction pipe 230 reaches and is maintained at a predetermined temperature. In addition, the gas exhaust pipe 231 is heated by the auxiliary heater 272 for the gas exhaust pipe 231 based on the temperature information detected by the temperature sensor provided in the auxiliary heater 272 such that the inner temperature of the gas exhaust pipe 231 reaches and is maintained at a predetermined temperature. In the present step, a state of the electrical conduction to the heater 206 is feedback-controlled based on the temperature information detected by the temperature sensor 207 such that the distribution of the inner temperature of the process chamber 201 is adjusted to a predetermined temperature distribution. Subsequently, by rotating the boat 217 by the rotator 254, the substrates 200 are rotated.

### <Film-Forming Step S203>

Subsequently, an alternate supply process (which is an example of a film-forming step S203) will be described. In the alternate supply process, different gases are alternately supplied to form a desired film on the substrate 200.

For example, in a first step of the alternate supply process, the first gas is supplied from the first gas supplier 310 to the process chamber 201, and in a subsequent second step of the alternate supply process, the second gas is supplied from the second gas supplier 320 to the process chamber 201 to form a desired film. Between the first step and the second step, a purge step is provided to exhaust the inner atmosphere of the process chamber 201. For example, by performing a combination of the first step, the purge step and the second step at least once, preferably a plurality of times, it is possible to form a silicon-containing film serving as the film on the substrate 200.

### <Returning to Normal Pressure Step S204>

After a predetermined process time has elapsed, the inner atmosphere of the process chamber 201 is replaced with the inert gas supplied from an inert gas supply source such as the inert gas supply sources 316 and 326, and the inner pressure of the process chamber 201 is returned to a normal pressure (atmospheric pressure).

### <Substrate Unloading Step S205>

Then, the seal cap 219 is lowered by the boat elevator 115 and the lower end of the manifold 209 is opened. The boat 217 with the substrates 200 processed as described above and charged therein is transferred (or unloaded) out of the reaction tube 203 through the lower end of the manifold 209 (boat unloading step). After the boat 217 is unloaded, the substrates 200 processed as described above are taken out of the boat 217 (substrate discharging step).

### Example of Process Conditions

For example, process conditions when the substrate 200 is processed by the substrate processing apparatus according to the present embodiments, for example, to form the silicon nitride film (Si₃N₄ film), are as follows:
A process pressure: from 10 Pa to 100 Pa;
The gases used to form the film: dichlorosilane (DCS, SiH₂Cl₂) gas and ammonia (NH₃) gas;
A supply flow rate of the DCS gas: from 100 sccm to 300 sccm;
A supply flow rate of the NH₃ gas: from 300 sccm to 1,000 sccm;
A process temperature in the reaction tube 203 heated by the heater wire 266: from 500° C. to 780° C.;
The inner temperature of the gas introduction pipe 230 heated by the auxiliary heater 271 for the gas introduction pipe 230: from 150° ° C. to the process temperature (which is within a range from 550° C. to 780° C.); and
The inner temperature of the gas exhaust pipe 231 heated by the auxiliary heater 272 for the gas exhaust pipe 231: from the process temperature (which is within the range from 550˜780° ° C. to 150° C.). The processing is performed on the substrate while maintaining each process condition to be constant at a predetermined within each range.

According to the present embodiments, it is possible to obtain one or more effects described below.
(a) The substrate processing apparatus includes: the reaction tube provided with the protrusion (that is, the gas introduction pipe), wherein the substrate is processed in the reaction tube; the first heating structure (that is, the first heater) configured to heat the reaction tube; the second heating structure (that is, the second heater) configured to heat the protrusion; and the heat insulator provided at the protrusion. Thereby, it is possible to suppress the heat radiation from the protrusion.
(b) The protrusion is disposed at the gas supply side through which the gas is supplied. Since the second heating structure heats the protrusion on the gas supply side through which the gas is supplied, it is possible to sufficiently preheat the gas to a temperature at which the gas can react, and it is also possible to efficiently process the substrate. In addition, when a liquid source material or a source material that easily liquefied at a normal temperature and the normal pressure is used as a source material of the gas, it is possible to prevent a liquefaction of the gas at the protrusion.
(c) The reaction tube includes the gas exhaust side protrusion (that is, the gas exhaust pipe) through which the gas is exhausted, and further includes the heat insulator provided on the gas exhaust side protrusion. Since the second heating structure heats the gas exhaust side protrusion (that is, the gas exhaust pipe) through which the gas is exhausted, it is possible to prevent the by-products from adhering to the gas exhaust side protrusion.
(d) The heat insulator is provided in contact with the gas supply side protrusion. Thereby, it is possible to suppress the heat radiation from the gas supply side protrusion.
(e) The heat insulator is provided in contact with the gas exhaust side protrusion. Thereby, it is possible to suppress the heat radiation from the gas exhaust side protrusion.
(f) The cover is provided at the position where the heat insulator is provided. Thereby, it is possible to suppress the heat escape.
(g) The second heating structure is wrapped around the protrusion. Thereby, it is possible to suppress the heat escape.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. For example, the embodiments described above are described in detail to clearly explain the technique of the present disclosure, and the technique of the present disclosure is not limited to those including an entirety of the configurations described herein. In addition, it is possible to add or eliminate a configuration of each embodiment, or replace a configuration of each embodiment with another configuration.

According to some embodiments of the present disclosure, it is possible to improve the uniformity of heating the substrate.

What is claimed is:

1. A substrate processing apparatus comprising:
a reaction tube provided with a protrusion, wherein a substrate is processed in the reaction tube;
a first heater configured to heat the reaction tube;
a second heater configured to heat the protrusion; and
a heat insulator provided at the protrusion.

2. The substrate processing apparatus of claim 1, wherein the protrusion comprises a gas supply side protrusion disposed at a gas supply side through which a gas is supplied.

3. The substrate processing apparatus of claim 2, wherein the heat insulator is provided at the gas supply side protrusion.

4. The substrate processing apparatus of claim 3, wherein the heat insulator is provided in contact with the gas supply side protrusion.

5. The substrate processing apparatus of claim 2, wherein the heat insulator is provided outside the gas supply side protrusion.

6. The substrate processing apparatus of claim 2, wherein an inlet port is provided on the heat insulator so as to prevent contacting the gas supply side protrusion.

7. The substrate processing apparatus of claim 1, wherein the protrusion comprises a gas exhaust side protrusion disposed at a gas exhaust side through which a gas is exhausted.

8. The substrate processing apparatus of claim 7, wherein the heat insulator is provided at the gas exhaust side protrusion.

9. The substrate processing apparatus of claim 8, wherein the heat insulator is provided outside the gas exhaust side protrusion.

10. The substrate processing apparatus of claim 7, wherein the heat insulator is provided in contact with the gas exhaust side protrusion.

11. The substrate processing apparatus of claim 7, wherein an outlet port is provided on the heat insulator so as to prevent contacting the gas exhaust side protrusion.

12. The substrate processing apparatus of claim 1, further comprising:
a cover provided at a position where the heat insulator is provided.

13. The substrate processing apparatus of claim 12, wherein the heat insulator is provided between the protrusion and the cover.

14. The substrate processing apparatus of claim 1, wherein the second heater is wrapped around the protrusion.

15. The substrate processing apparatus of claim 1, further comprising:
a substrate retainer configured to accommodate the substrate and one or more substrates in a multistage manner in a vertical direction.

16. The substrate processing apparatus of claim 15, wherein the substrate and the one or more substrates are arranged in a height direction between an upper end and a lower end of the protrusion.

17. The substrate processing apparatus of claim 1, wherein the first heater is provided outside the reaction tube.

18. A substrate processing method comprising:
(a) transferring a substrate into a reaction tube of a substrate processing apparatus comprising:
the reaction tube provided with a protrusion, wherein the substrate is processed in the reaction tube;
a first heater configured to heat the reaction tube;
a second heater configured to heat the protrusion; and
a heat insulator provided at the protrusion;
(b) supplying a gas onto the substrate; and
(c) processing the substrate.

19. A non-transitory computer-readable recording medium storing a program that causes a substrate processing apparatus, by a computer, to perform a process comprising the substrate processing method of claim 18.

20. A method of manufacturing a semiconductor device, comprising:
(a) transferring a substrate into a reaction tube of a substrate processing apparatus comprising:
the reaction tube provided with a protrusion, wherein the substrate is processed in the reaction tube;
a first heater configured to heat the reaction tube;
a second heater configured to heat the protrusion; and
a heat insulator provided at the protrusion;
(b) supplying a gas onto the substrate; and
(c) processing the substrate.
